(19) United States
(12) Patent Application Publication
(10) Pub. No.: US 2026/0013066 A1
(43) Pub. Date: Jan. 8, 2026

(54) HANDLE ASSEMBLY, RELATED SERVER DEVICE AND RELATED SERVER SYSTEM

(71) Applicant: Wiwynn Corporation, New Taipei City (TW)

(72) Inventors: Yong-Yuan Yang, New Taipei City (TW); Yu-Hsuan Wang, New Taipei City (TW); Jing-Suei Gao, New Taipei City (TW); Ching-Cheng Zou, New Taipei City (TW)

(73) Assignee: Wiwynn Corporation, New Taipei City (TW)

(21) Appl. No.: 19/001,360

(22) Filed: Dec. 24, 2024

(30) Foreign Application Priority Data
Jul. 3, 2024 (TW) 113124850

(51) Int. Cl. H05K 7/14

(52) U.S. Cl. CPC H05K 7/1487

(57) ABSTRACT

A handle assembly is provided and includes a rotary component and a stabilization mechanism. The rotary component includes a first side and a second side opposite to the first side. The stabilization mechanism includes a first movable component, a first resilient component, a second movable component and a second resilient component. The first movable component is extendable or retractable relative to the first side of the rotary component. The first resilient component is abutted between the first movable component and the rotary component. The second movable component is extendable or retractable relative to the second side of the rotary component. The second resilient component is abutted between the second movable component and the rotary component. Besides, a related server device having the aforementioned handle assembly, and a related server system having the aforementioned server device, are also provided.

### BACKGROUND OF THE INVENTION

### 1. Field of the Invention

The present invention relates to a handle assembly, a related server device and a related server system, and more specifically, to a handle assembly with enhanced operability, a related server device with the aforementioned handle assembly, and a related server system with the aforementioned server device.

### 2. Description of the Prior Art

In order to meet different requirements in different application fields, modularity has gradually become a mainstream trend of electronic apparatuses. Taking a server system as an example, the server system usually includes a rack and a server device detachably mounted on the rack, and the server device is usually equipped with a rotary handle for manual operation of mounting or detachment. However, when the rotary handle is in a non-fold state, the rotary handle sags due to gravity, which causes difficulty in a folding operation of the handle assembly. Furthermore, in order to solve a problem of difficulty in folding, some server devices have restraining mechanisms for preventing the rotary handles from sagging to ensure the rotary handles to rotate horizontally. However, when the rotary handle is located at a higher or a lower position, such restraining mechanism makes it hard for the user to operate the rotary handle.

### SUMMARY OF THE INVENTION

Therefore, it is an objective of the present invention to provide a handle assembly with enhanced operability, a related server device with the aforementioned handle assembly, and a related server system with the aforementioned server device, for solving the aforementioned problem.

In order to achieve the aforementioned objective, the present invention discloses a handle assembly. The handle assembly includes a rotary component and a stabilization mechanism. The rotary component includes a first side and a second side opposite to the first side. The stabilization mechanism includes a first movable component, a first resilient component, a second movable component and a second resilient component. The first movable component is extendable or retractable relative to the first side of the rotary component. The first resilient component is abutted between the first movable component and the rotary component. The second movable component is extendable or retractable relative to the second side of the rotary component. The second resilient component is abutted between the second movable component and the rotary component.

Besides, in order to achieve the aforementioned objective, the present invention further discloses a server device. The server device includes a server body and a handle assembly. The handle assembly includes a rotary component and a stabilization mechanism. The rotary component is connected to the server body and rotatable relative to the server body. The rotary component includes a first side and a second side opposite to the first side. The stabilization mechanism includes a first movable component, a first resilient component, a second movable component and a second resilient component. The first movable component is extendable or retractable relative to the first side of the rotary component. The first resilient component is abutted between the first movable component and the rotary component. The second movable component is extendable or retractable relative to the second side of the rotary component. The second resilient component is abutted between the second movable component and the rotary component.

In addition, in order to achieve the aforementioned objective, the present invention further discloses a server system. The server system includes a rack and a server device. The server device includes a server body and a handle assembly. The server body is mounted on the rack. The handle assembly includes a rotary component and a stabilization mechanism. The rotary component is connected to the server body and rotatable relative to the server body. The rotary component includes a first side and a second side opposite to the first side. The stabilization mechanism includes a first movable component, a first resilient component, a second movable component and a second resilient component. The first movable component is extendable or retractable relative to the first side of the rotary component. The first resilient component is abutted between the first movable component and the rotary component. The second movable component is extendable or retractable relative to the second side of the rotary component. The second resilient component is abutted between the second movable component and the rotary component.

In summary, the present invention utilizes the stabilization mechanism to prevent the rotary component from sagging due to gravity, facilitating the rotary component to be folded successfully. Furthermore, the stabilization mechanism of the present invention also enables the rotary component to be oriented obliquely in upward or downward directions according to an applied force direction exerted by a user, facilitating the user to rotate the rotary component easily. Therefore, the present invention has enhanced operability.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial diagram of a server system according to an embodiment of the present invention.

FIG. 2 and FIG. 3 are partial exploded diagrams of a server device at different views according to the embodiment of the present invention.

FIG. 4 and FIG. 5 are partial exploded diagrams of a handle assembly at different views according to the embodiment of the present invention.

FIG. 6 is a partial sectional diagram of the handle assembly according to the embodiment of the present invention.

FIG. 7 is a partial diagram of the server device as the handle assembly is located at a non-cooperating position according to the embodiment of the present invention.

FIG. 8 is a partial sectional diagram of the server device as the handle assembly is located at the non-cooperating position according to the embodiment of the present invention.

FIG. 9 is a partial diagram of the server device as the handle assembly is located at a cooperating position according to the embodiment of the present invention.

FIG. 10 is a partial sectional diagram of the server device as the handle assembly is located at the cooperating position according to the embodiment of the present invention.

### DETAILED DESCRIPTION

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “left”, “right”, “front”, “back”, etc., is used with reference to the orientation of the Figure(s) being described. The components of the present invention can be positioned in a number of different orientations. As such, the directional terminology is used for purposes of illustration and is in no way limiting. Accordingly, the drawings and descriptions will be regarded as illustrative in nature and not as restrictive. Also, if not specified, the term “connect” is intended to mean either an indirect or direct mechanical connection. Thus, if a first device is coupled to a second device, that connection may be through a direct mechanical connection, or through an indirect mechanical connection via other devices and connections.

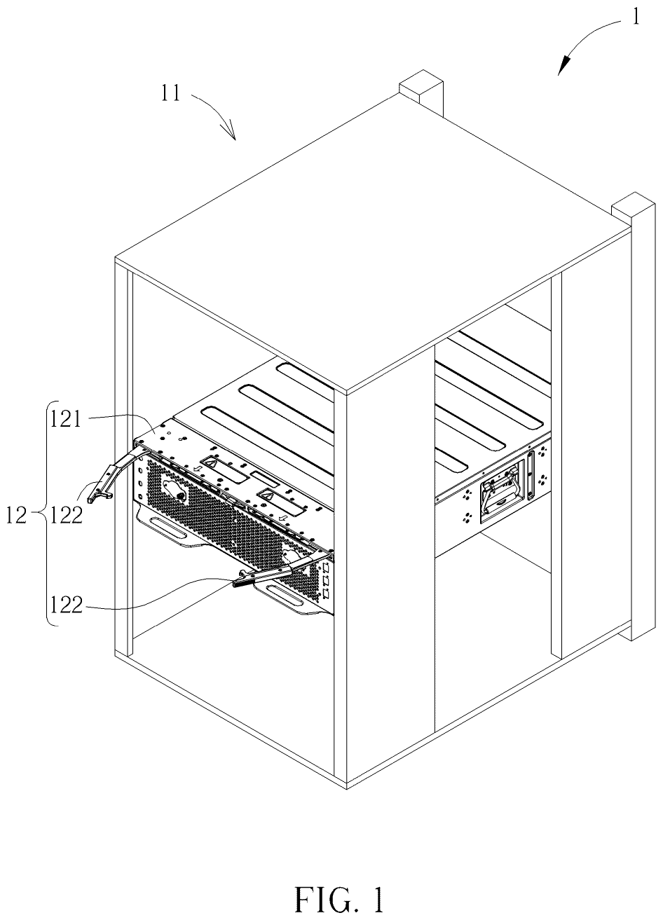

Referring to FIG. 1, which is a partial diagram of a server system 1 according to an embodiment of the present invention. As shown in FIG. 1, the server system 1 includes a rack 11 and a server device 12. The server device 12 includes a server body 121 and two handle assemblies 122. The server body 121 is mounted on the rack 11. The two handle assemblies 122 are configured to be operated by a user for mounting the server body 121 on the rack 11 or detaching the server body 121 from the rack 11. It should be noticed that the number of the handle assemblies is not limited to this embodiment. For example, in another embodiment, the server device can include only one handle assembly. Besides, in this embodiment, the two handle assemblies 122 are located at a left side and a right side of the server body 121, respectively, and have substantially symmetrical structures. Detailed description for the handle assembly 122 at one side is provided as follow for simplicity.

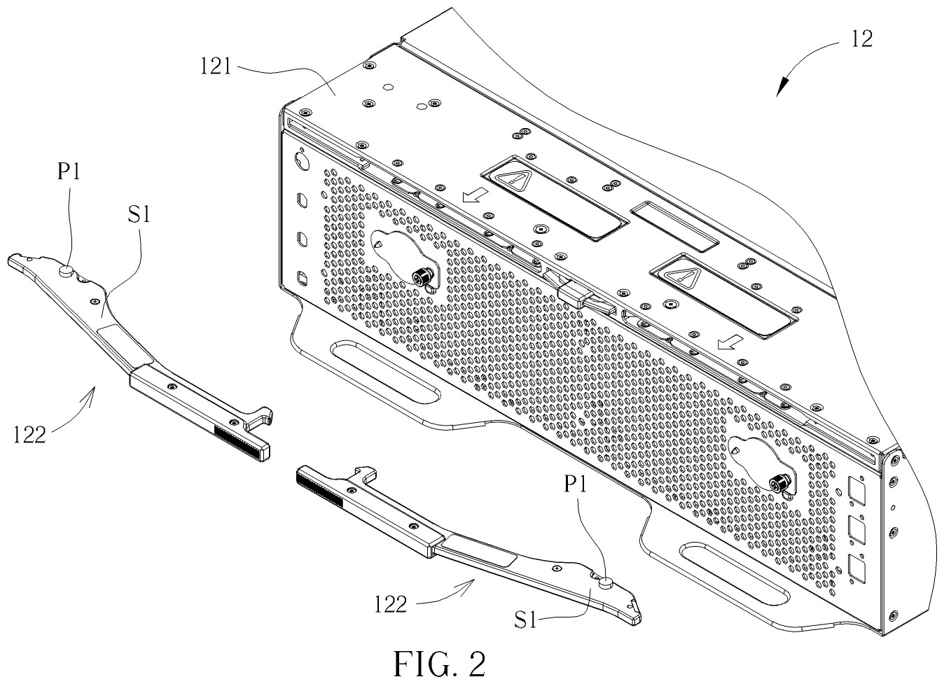

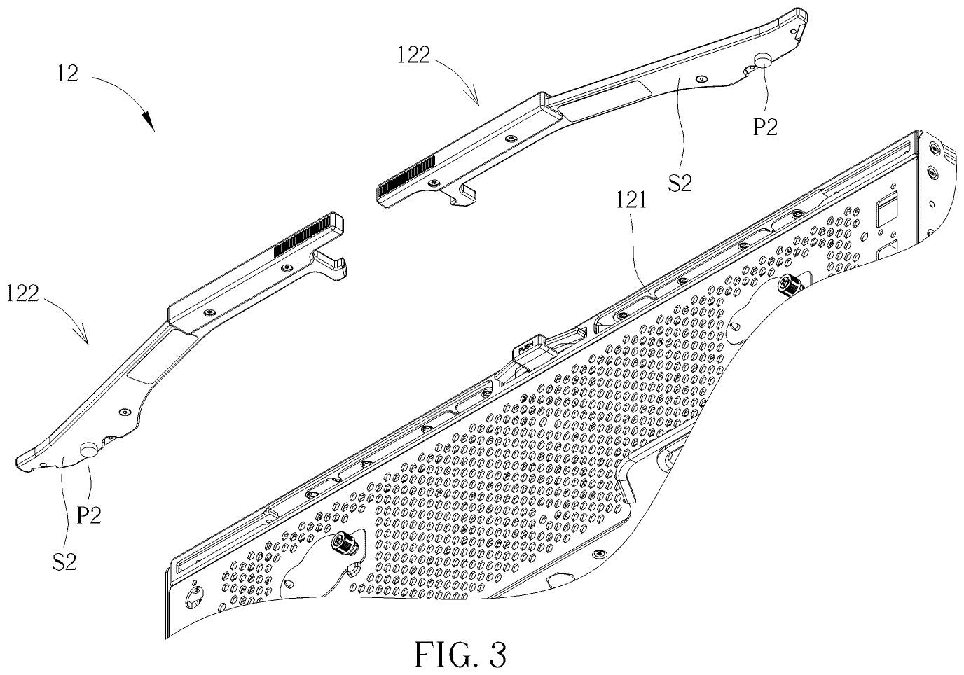

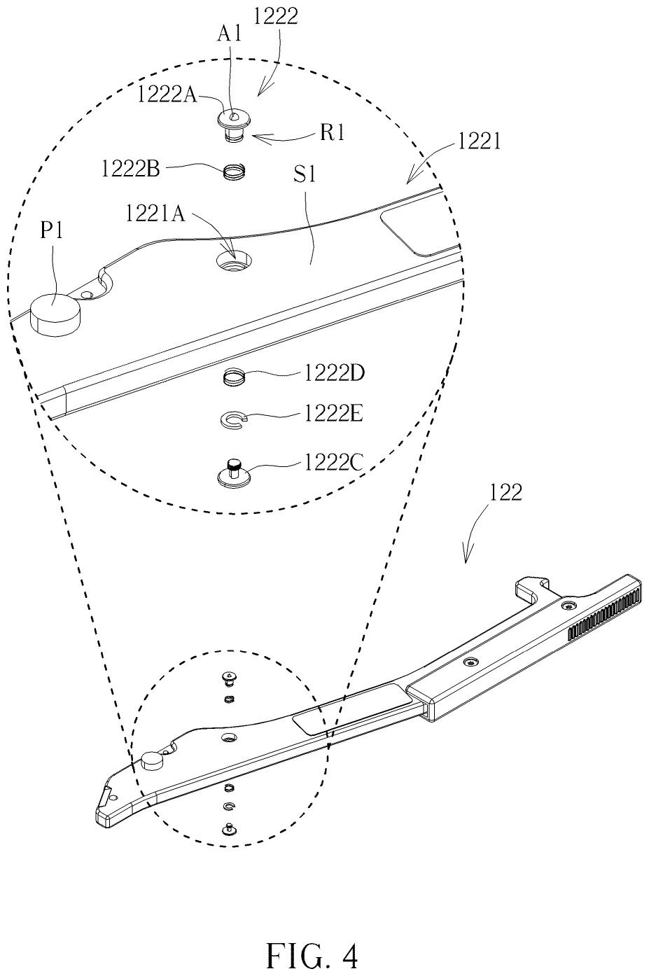

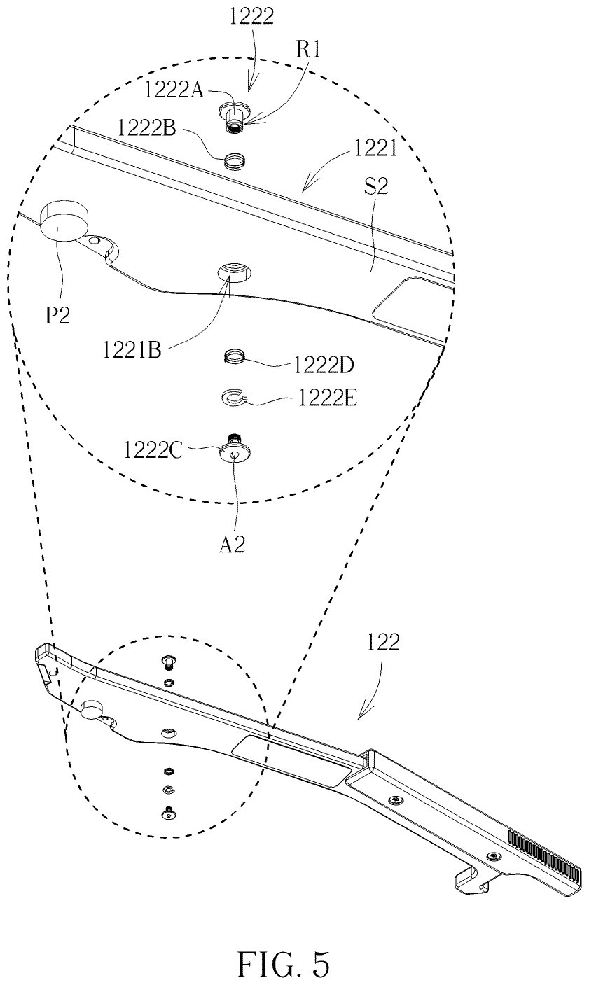

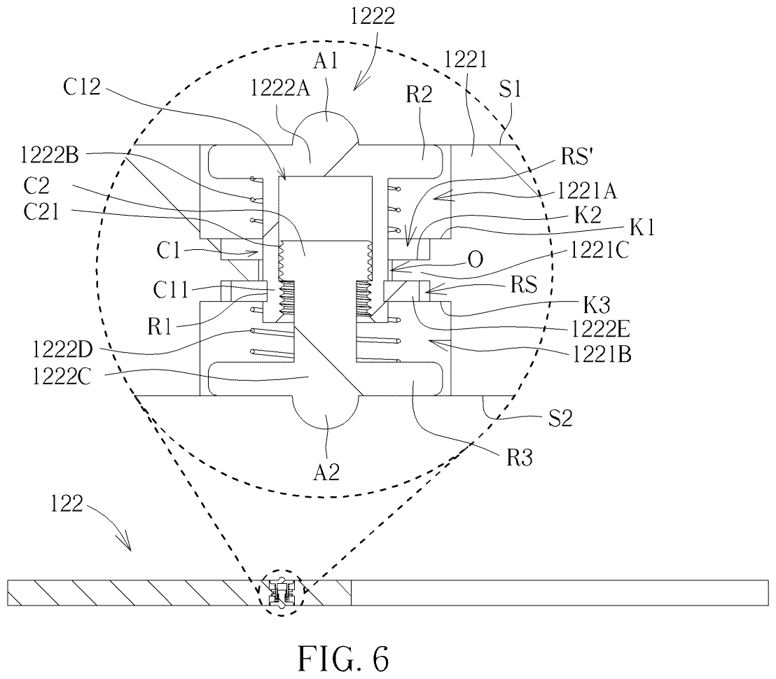

References are made from FIG. 2 to FIG. 6. FIG. 2 and FIG. 3 are partial exploded diagrams of the server device 12 at different views according to the embodiment of the present invention. FIG. 4 and FIG. 5 are partial exploded diagrams of the handle assembly 122 at different views according to the embodiment of the present invention. FIG. 6 is a partial sectional diagram of the handle assembly 122 according to the embodiment of the present invention. As shown in FIG. 2 to FIG. 6, the handle assembly 122 includes a rotary component 1221 and a stabilization mechanism 1222. The rotary component 1221 is connected to the server body 121 and rotatable relative to the server body 121. The rotary component 1221 includes a first side S1 and a second side S2 opposite to the first side S1. In this embodiment, the first side S1 and the second side S2 of the rotary component 1221 can be an upper side and a lower side of the rotary component 1221. Furthermore, a first rotating pin P1 and a second rotating pin P2 protrude from the first side S1 and the second side S2 of the rotary component 1221, respectively, and the server body 121 can include a first pin hole and a second pin hole, which are not shown in the figures, allowing the first rotating pin P1 and the second rotating pin P2 to penetrate therethrough, such that the rotary component 1221 is rotatable relative to the server body 121 by a rotating cooperation of the first rotating pin P1 and the first pin hole and a rotating cooperation of the second rotating pin P2 and the second pin hole. However, the present invention is not limited to this embodiment. Understandably, in another embodiment, the first side and the second side of the rotary component can be the lower side and the upper side of the rotary component. Alternatively, in another embodiment, the first pin hole and the second pin hole can be formed on the first side and the second side of the rotary component, respectively, and the first rotating pin and the second rotating pin can protrude from the server body and penetrate through the first pin hole and the second pin hole, respectively, such that the rotary component is rotatable relative to the server body by the rotating cooperation of the first rotating pin and the first pin hole and the rotating cooperation of the second rotating pin and the second pin hole.

As shown in FIG. 4 to FIG. 6, the stabilization mechanism 1222 includes a first movable component 1222A, a first resilient component 1222B, a second movable component 1222C and a second resilient component 1222D. The first movable component 1222A is extendable or retractable relative to the first side S1 of the rotary component 1221. The first resilient component 1222B is abutted between the first movable component 1222A and the rotary component 1221. The second movable component 1222C is extendable or retractable relative to the second side S2 of the rotary component 1221. The second resilient component 1222D is abutted between the second movable component 1222C and the rotary component 1221. For example, the first resilient component 1222B can be sleeved on the first movable component 1222A, and the second resilient component 1222D can be sleeved on the second movable component 1222C. The first movable component 1222A and the second movable component 1222C can be driven by the first resilient component 1222B and the second resilient component 1222D to resiliently abut against the two opposite walls of the server body 121, respectively, such that the rotary component 1221 can not only be retained in a horizontal state by overcoming gravity during rotation of the rotary component 1221, but also move to an oblique state, e.g., a upwardly oblique state or a downwardly oblique state, according to an applied force direction exerted by the user and return back to the horizontal state after releasing the rotary component 1221. Understandably, a resilient coefficient of the first resilient component 1222B can be identical to or different from a resilient coefficient of the second resilient component 1222D. It depends on practical demands. For example, the resilient coefficient of the first resilient component 1222B can be determined according to a required resilient abutting force generated by the first resilient component 1222B resiliently abutting against the corresponding wall of the server body 121, and the resilient coefficient of the second resilient component 1222D can be determined according to a required resilient abutting force generated by the second resilient component 1222D resiliently abutting against the corresponding wall of the server body 121.

Specifically, in order to restrict the first movable component 1222A and the second movable component 1222C to move relative to each other and/or extend or retract relative to the rotary component 1221 within a predetermined range, as shown in FIG. 4 to FIG. 6, a first accommodating space 1221A, a second accommodating space 1221B and an abutting protruding edge 1221C are formed on the rotary component 1221. The abutting protruding edge 1221C is located between the first accommodating space 1221A and the second accommodating space 1221B. The first accommodating space 1221A and the second accommodating space 1221B are located adjacent to the first side S1 and the second side S2 of the rotary component 1221, respectively. A through hole O is formed on the abutting protruding edge 1221C and communicated with the first accommodating space 1221A and the second accommodating space 1221B. The first movable component 1222A is penetrated through the through hole O from the first accommodating space 1221A and partially located inside the second accommodating space 1221B. The second movable component 1222C is at least partially located inside the first movable component 1222A and extendable or retractable relative to the first movable component 1222A. In this embodiment, the first movable component 1222A is configured to penetrate through the through hole O from an upper accommodating space and partially located inside a lower accommodating space from top to bottom. However, in another embodiment, if the first side and the second side of the rotary component are the lower side and the upper side of the rotary component, respectively, the first movable component can be configured to penetrate through the through hole from the lower accommodating space and partially located inside the upper accommodating space from bottom to top.

The first movable component 1222A includes a first cooperating portion C1. The second movable component 1222C includes a second cooperating portion C2 configured to cooperate with the first cooperating portion C1 for restraining an extending stroke or a retracting stroke of the second movable component 1222C relative to the first movable component 1222A. Specifically, the first cooperating portion C1 can include a first cooperating structure C11 and a chamber structure C12. The second cooperating portion C2 can include a second cooperating structure C21. The second cooperating portion C2 can enter into the chamber structure C12 by a cooperation of the second cooperating structure C21 and the first cooperating structure C11, and the second cooperating portion C2 can be restricted to move within the chamber structure C12 after entering into the chamber structure C12 for restraining the extending stroke or the retracting stroke of the second movable component 1222C relative to the first movable component 1222A.

In this embodiment, the first cooperating structure C11 and the second cooperating structure C21 can be an internal threaded structure and an external threaded structure, respectively, such that the second cooperating portion C2 can enter into the chamber structure C12 by relative rotation of the second cooperating structure C21 and the first cooperating structure C11. However, the present invention is not limited to this embodiment. For example, in another embodiment, the first cooperating structure and the second cooperating structure can be an internal spline structure and an external spline structure, respectively, and the second cooperating portion can enter into the chamber structure by relative sliding movement of the second cooperating structure and the first cooperating structure.

Besides, in this embodiment, as shown in FIG. 6, an accommodating recess RS' is formed on a first abutting wall K1 of the first accommodating space 1221A, and another accommodating recess RS is formed on a second abutting wall K3 of the second accommodating space 1221B. The abutting protruding edge 1221C is defined between the two accommodating recesses RS′, RS.

Furthermore, as shown in FIG. 4 to FIG. 6, the stabilization mechanism 1222 further includes an engaging component 1222E. The first movable component 1222A includes an engaging recessed portion R1. The engaging component 1222E is engaged with the engaging recessed portion R1 and configured to abut against the abutting protruding edge 1221C for restraining an extending stroke of the first movable component 1222A relative to the rotary component 1221. Specifically, the engaging recessed portion R1 can be formed on an end of the first movable component 1222A adjacent to the second accommodating space 1221B, and the engaging component 1222E can be a C-shaped clip.

In addition, as shown in FIG. 6, the first movable component 1222A further includes a first stopping protrusion R2 formed on an end of the first movable component 1222A located inside the first accommodating space 1221A and configured to abut against the first abutting wall K1 of the first accommodating space 1221A for restraining a retracting stroke of the first movable component 1222A relative to the rotary component 1221. The first resilient component 1222B is abutted between the first stopping protrusion R2 and an abutting wall K2 of the accommodating recess RS′ for driving the first movable component 1222A to resiliently abut against the corresponding wall of the server body 121. Similarly, the second movable component 1222C further includes a second stopping protrusion R3 formed on an end of the second movable component 1222C located inside the second accommodating space 1221B and configured to abut against the second abutting wall K3 of the second accommodating space 1221B for restraining a retracting stroke of the second movable component 1222C relative to the rotary component 1221. The second resilient component 1222D is abutted between the second stopping protrusion R3 and the engaging component 1222E for driving the second movable component 1222C to resiliently abut against the corresponding wall of the server body 121. Understandably, in another embodiment, the first resilient component can be abutted between the first stopping protrusion of the first movable component and the first abutting wall of the first accommodating space, and the second resilient component can be abutted between the second stopping protrusion of the second movable component and the second abutting wall of the second accommodating space, i.e., the first stopping protrusion can be configured not to abut against the first abutting wall directly, and the second stopping protrusion can be configured not to abut against the second abutting wall directly.

As shown in FIG. 4 to FIG. 6, the first movable component 1222A further includes a first arc-shaped abutting portion A1. The second movable component 1222C further includes a second arc-shaped abutting portion A2. The first arc-shaped abutting portion A1 and the second arc-shaped abutting portion A2 are configured to resiliently abut against the two walls of the server body 121, i.e., the first movable component 1222A and the second movable component 1222C can be driven by the first resilient component 1222B and the second resilient component 1222D to resiliently abut against the two walls of the server body 121 by the first arc-shaped abutting portion A1 and the second arc-shaped abutting portion A2, respectively. The first arc-shaped abutting portion A1 and the second arc-shaped abutting portion A2 can reduce a frictional force between the first movable component 1222A and the corresponding wall of the server body 121 and a frictional force between the second movable component 1222C and the corresponding wall of the server body 121 for facilitating the smooth rotation of the rotary component 1221. Understandably, a radius of the first arc-shaped abutting portion A1 can be identical to or different from a radius of the second arc-shaped abutting portion A2. It depends on practical demands. For example, the radius of the first arc-shaped abutting portion A1 can be determined according to a gap between the first side S1 of the rotary component 1221 and the corresponding wall of the server body 121, and the radius of the second arc-shaped abutting portion A2 can be determined according to a gap between the second side S2 of the rotary component 1221 and the corresponding wall of the server body 121.

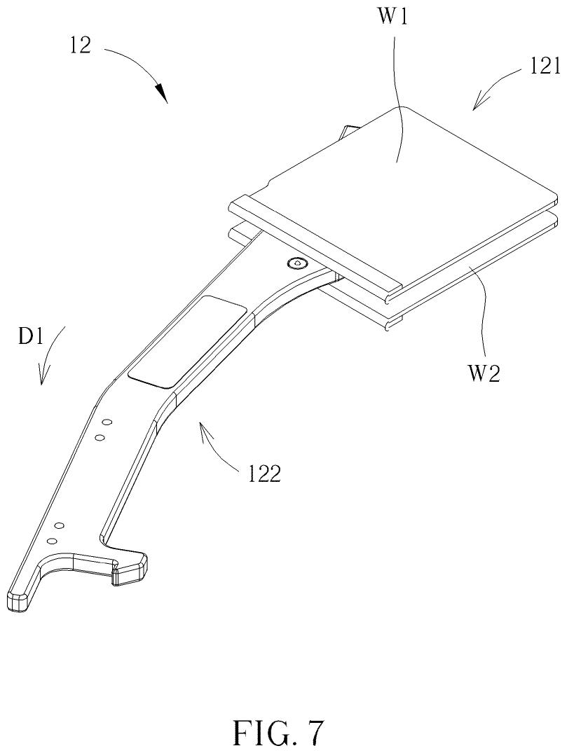

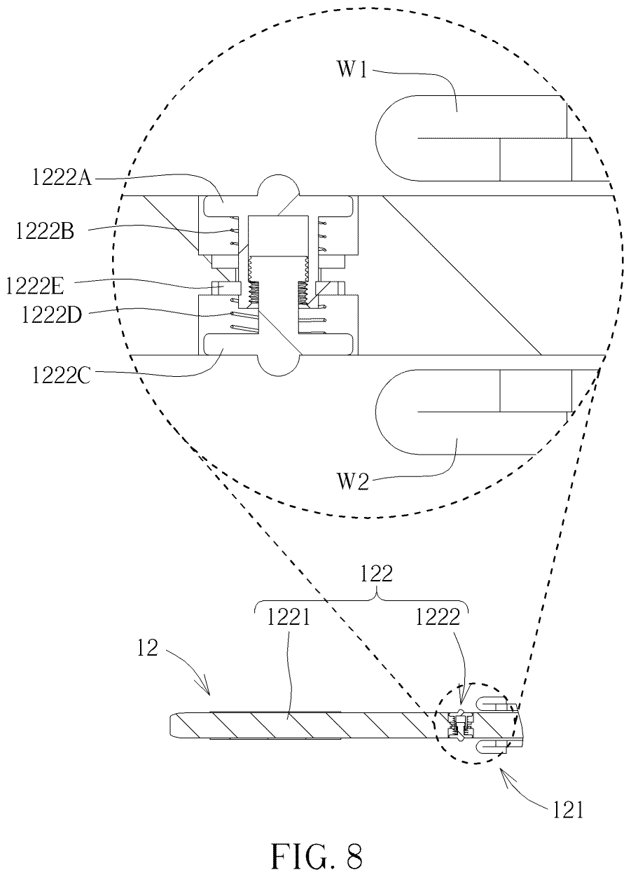

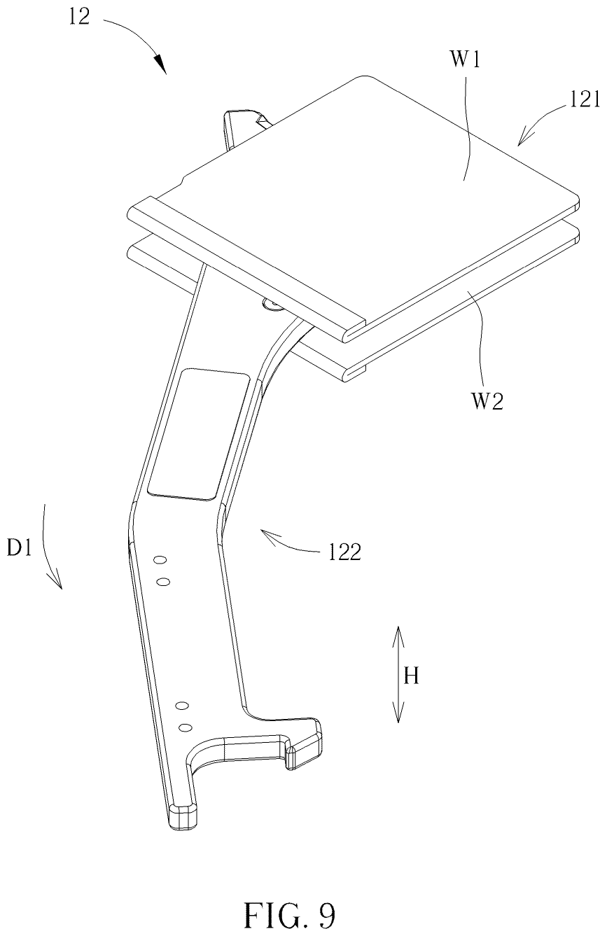

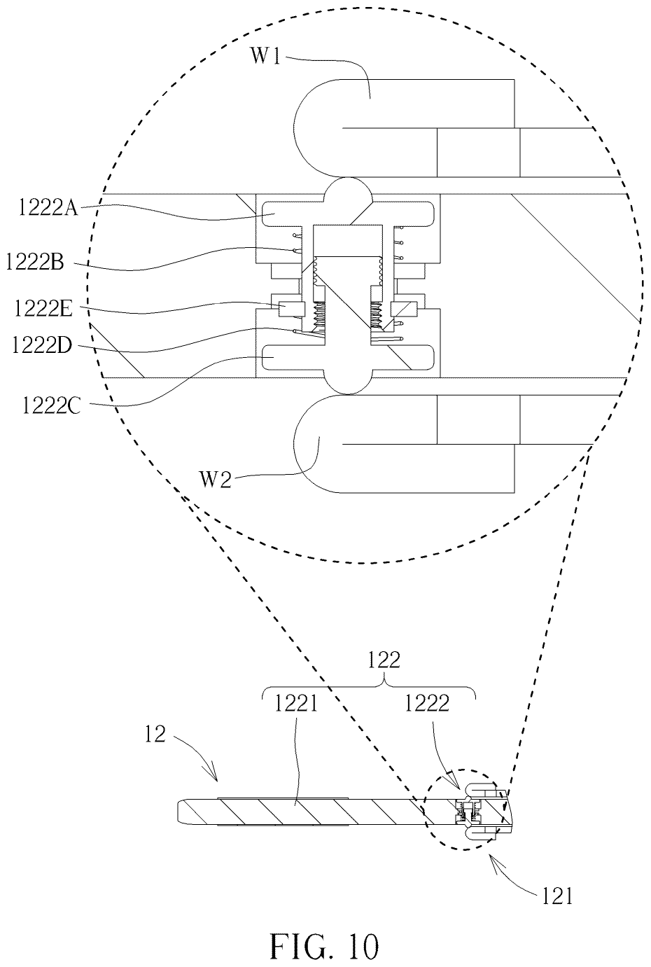

References are made from FIG. 7 to FIG. 10. FIG. 7 is a partial diagram of the server device 12 as the handle assembly 122 is located at a non-cooperating position according to the embodiment of the present invention. FIG. 8 is a partial sectional diagram of the server device 12 as the handle assembly 122 is located at the non-cooperating position according to the embodiment of the present invention. FIG. 9 is a partial diagram of the server device 12 as the handle assembly 122 is located at a cooperating position according to the embodiment of the present invention. FIG. 10 is a partial sectional diagram of the server device 12 as the handle assembly 122 is located at the cooperating position according to the embodiment of the present invention. The handle assembly 122 can be rotated from the non-cooperating position as shown in FIG. 7 and FIG. 8 through the cooperating position as shown in FIG. 9 and FIG. 10 along a first direction D1, e.g., a folding direction, relative to the server body 121 to be folded. As shown in FIG. 7 and FIG. 8, when the handle assembly 122 is located at the non-cooperating position, the first movable component 1222A and the second movable component 1222C of the stabilization mechanism 1222 have not yet abutted against a first wall W1 and a second wall W2 of the server body 121. When the handle assembly 122 rotates from the non-cooperating position as shown in FIG. 7 and FIG. 8 to the cooperating position as shown in FIG. 9 and FIG. 10, the first movable component 1222A and the second movable component 1222C of the stabilization mechanism 1222 move toward each other to resiliently compress the first resilient component 1222B and the second resilient component 1222D, and the first movable component 1222A and the second movable component 1222C resiliently abut against the first wall W1 and the second wall W2 of the server body 121 in response to the resilient abutting force generated by the first resilient component 1222B and the second resilient component 1222D, respectively. Afterwards, during rotation of the rotary component 1221 relative to the server body 121 from the cooperating position along the first direction D1, due to the configuration of that the first movable component 1222A and the second movable component 1222C resiliently abut against the first wall W1 and the second wall W2 of the server body 121, the rotary component 1221 can be retained in the horizontal state by overcoming gravity. Besides, when the first movable component 1222A and the second movable component 1222C resiliently abut against the first wall W1 and the second wall W2 of the server body 121, the resilient deformation of the first resilient component 1222B and the resilient deformation of the second resilient component 1222D can enable the rotary component 1221 to move to an oblique state, e.g., a upwardly oblique state or a downwardly oblique state relative to a height direction H, according to an applied force direction exerted by the user and return back to the horizontal state after releasing the rotary component 1221, allowing the user to rotatably fold the handle assembly 122 and/or the rotary component 1221 easily.

In summary, the present invention utilizes the stabilization mechanism to prevent the rotary component from sagging due to gravity, facilitating the rotary component to be folded successfully. Furthermore, the stabilization mechanism of the present invention also enables the rotary component to be oriented obliquely in upward or downward directions according to an applied force direction exerted by a user, facilitating the user to rotate the rotary component easily. Therefore, the present invention has enhanced operability.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A handle assembly comprising:
a rotary component comprising a first side and a second side opposite to the first side; and
a stabilization mechanism comprising:
a first movable component extendable or retractable relative to the first side of the rotary component;
a first resilient component abutted between the first movable component and the rotary component;
a second movable component extendable or retractable relative to the second side of the rotary component; and
a second resilient component abutted between the second movable component and the rotary component.

2. The handle assembly of claim 1, wherein a first accommodating space, a second accommodating space and an abutting protruding edge are formed on the rotary component, the abutting protruding edge is located between the first accommodating space and the second accommodating space, a through hole is formed on the abutting protruding edge and communicated with the first accommodating space and the second accommodating space, and the first movable component is penetrated through the through hole from the first accommodating space and partially located inside the second accommodating space.

3. The handle assembly of claim 2, wherein the stabilization mechanism further comprises an engaging component, the first movable component comprises an engaging recessed portion, and the engaging component is engaged with the engaging recessed portion and configured for abutting against the abutting protruding edge.

4. The handle assembly of claim 2, wherein the first movable component comprises a first stopping protrusion formed on an end of the first movable component located inside the first accommodating space.

5. The handle assembly of claim 1, wherein the second movable component is at least partially located inside the first movable component and extendable or retractable relative to the first movable component.

6. The handle assembly of claim 1, wherein the first movable component comprises a first cooperating portion, and the second movable component comprises a second cooperating portion configured to cooperate with the first cooperating portion for restraining an extending stroke or a retracting stroke of the second movable component relative to the first movable component.

7. The handle assembly of claim 1, wherein the first movable component comprises a first arc-shaped abutting portion, the second movable component comprises a second arc-shaped abutting portion, and a radius of the first arc-shaped abutting portion is identical to or different from a radius of the second arc-shaped abutting portion.

8. The handle assembly of claim 1, wherein a resilient coefficient of the first resilient component is identical to or different from a resilient coefficient of the second resilient component.

9. A server device comprising:
a server body; and
a handle assembly comprising:
a rotary component connected to the server body and rotatable relative to the server body, the rotary component comprising a first side and a second side opposite to the first side; and
a stabilization mechanism comprising:
a first movable component extendable or retractable relative to the first side of the rotary component;
a first resilient component abutted between the first movable component and the rotary component;
a second movable component extendable or retractable relative to the second side of the rotary component; and
a second resilient component abutted between the second movable component and the rotary component.

10. The server device of claim 9, wherein a first accommodating space, a second accommodating space and an abutting protruding edge are formed on the rotary component, the abutting protruding edge is located between the first accommodating space and the second accommodating space, a through hole is formed on the abutting protruding edge and communicated with the first accommodating space and the second accommodating space, and the first movable component is penetrated through the through hole from the first accommodating space and partially located inside the second accommodating space.

11. The server device of claim 10, wherein the stabilization mechanism further comprises an engaging component, the first movable component comprises an engaging recessed portion, and the engaging component is engaged with the engaging recessed portion and configured for abutting against the abutting protruding edge.

12. The server device of claim 10, wherein the first movable component comprises a first stopping protrusion formed on an end of the first movable component located inside the first accommodating space.

13. The server device of claim 9, wherein the second movable component is at least partially located inside the first movable component and extendable or retractable relative to the first movable component.

14. The server device of claim 9, wherein the first movable component comprises a first cooperating portion, and the second movable component comprises a second cooperating portion configured to cooperate with the first cooperating portion for restraining an extending stroke or a retracting stroke of the second movable component relative to the first movable component.

15. The server device of claim 9, wherein the first movable component comprises a first arc-shaped abutting portion, the second movable component comprises a second arc-shaped abutting portion, and a radius of the first arc-shaped abutting portion is identical to or different from a radius of the second arc-shaped abutting portion.

16. A server system comprising:
a rack; and
a server device comprising:
a server body mounted on the rack; and
a handle assembly comprising:
a rotary component connected to the server body and rotatable relative to the server body, the rotary component comprising a first side and a second side opposite to the first side; and
a stabilization mechanism comprising:
a first movable component extendable or retractable relative to the first side of the rotary component;
a first resilient component abutted between the first movable component and the rotary component;
a second movable component extendable or retractable relative to the second side of the rotary component; and
a second resilient component abutted between the second movable component and the rotary component.

17. The server system of claim 16, wherein a first accommodating space, a second accommodating space and an abutting protruding edge are formed on the rotary component, the abutting protruding edge is located between the first accommodating space and the second accommodating space, a through hole is formed on the abutting protruding edge and communicated with the first accommodating space and the second accommodating space, and the first movable component is penetrated through the through hole from the first accommodating space and partially located inside the second accommodating space.

18. The server system of claim 17, wherein the stabilization mechanism further comprises an engaging component, the first movable component comprises an engaging recessed portion, and the engaging component is engaged with the engaging recessed portion and configured for abutting against the abutting protruding edge.

19. The server system of claim 16, wherein the second movable component is at least partially located inside the first movable component and extendable or retractable relative to the first movable component.

20. The server system of claim 16, wherein the first movable component comprises a first arc-shaped abutting portion, the second movable component comprises a second arc-shaped abutting portion, and a radius of the first arc-shaped abutting portion is identical to or different from a radius of the second arc-shaped abutting portion.
